(19) United States
(12) Patent Application Publication
(10) Pub. No.: US 2007/0023869 A1
(43) Pub. Date: Feb. 1, 2007

(54) Vapor phase deposition apparatus and vapor phase deposition method

(75) Inventors: Hiroshi Furutani, Shizuoka (JP); Yoshikazu Moriyama, Shizuoka (JP); Seiichi Nakazawa, Shizuoka (JP); Kunihiko Suzuki, Shizuoka (JP); Hideki Arai, Shizuoka (JP); Satoshi Inada, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: NuFLARE TECHNOLOGY, INC.

(21) Appl. No.: 11/494,649

(22) Filed: Jul. 28, 2006

(30) Foreign Application Priority Data
Jul. 29, 2005 (JP) 2005-219944
Jan. 13, 2006 (JP) 2006-006018
Apr. 13, 2006 (JP) 2006-110533

(51) Int. Cl. H01L 23/58

(52) U.S. Cl. 257/629

(57) ABSTRACT

A vapor phase deposition apparatus includes a chamber, a support table disposed in the chamber and adapted to support a substrate in the chamber, a first passage connected to the chamber and adapted to supply gas to the chamber to form a film on the substrate, and a second passage connected to the chamber and adapted to discharge the gas from the chamber. The support table includes a first depressed portion and a second depressed portion formed in a bottom part of the first depressed portion, a bottom face of the second depressed portion for supporting the substrate.

### CROSS-REFERENCE TO RELATED APPLICATION

This application is based upon and claims the benefit of priority from prior Japanese Patent Application No. JP 2005-219944 filed on Jul. 29, 2005 in Japan, prior Japanese Patent Application No. JP 2006-006018 filed on Jan. 13, 2006 in Japan, and prior Japanese Patent Application No. JP 2006-110533 filed on Apr. 13, 2006 in Japan, the entire contents of which are incorporated herein by reference.

### BACKGROUND OF THE INVENTION

1. Field of the Invention

The present invention relates to a vapor phase deposition apparatus and method. And for example, the present invention relates to a shape of a support member for supporting a substrate such as a silicon wafer in an epitaxial growth apparatus.

2. Related Art

In the manufacture of a semiconductor device such as a very high speed bipolar or a very high speed CMOS, an epitaxial growth technique for a single crystal having its impurity concentration and film thickness controlled is indispensable for enhancing the performance of the semiconductor devices.

For an epitaxial growth for causing a single crystal thin film to be vapor phase grown over a semiconductor substrate such as a silicon wafer, an atmospheric chemical vapor deposition method is generally used. According to circumstances, a low pressure chemical vapor deposition (LP-CVD) method is used. A semiconductor substrate such as a silicon wafer is disposed in a reactor and is heated and rotated in a state in which the inside of the reactor is held in an atmospheric pressure (0.1 MPa (760 Torr)) or a vacuum having a predetermined degree of vacuum, and at the same time, a raw gas containing a silicon source and a dopant such as a boron compound, an arsenic compound or a phosphorus compound is supplied. Then, the thermal decomposition or hydrogen reduction of the raw gas is carried out over a surface of the heated semiconductor substrate, and a silicon epitaxial film doped with boron (B), phosphorus (P) or arsenic (As) is grown (see Published Unexamined Japanese Patent Application No. 09-194296 (JP-A-09-194296), for example).

Moreover, the epitaxial growth technique is also used for manufacturing a power semiconductor, such as N-base (may be P-base) of an IGBT (insulated gate bipolar transistor) or N-base (may be P-base) of power MOS transistor. In the power semiconductor such as the IGBT, for example, a silicon epitaxial film having a thickness of several tens μm or more is required.

FIG. 26 is a top view showing an example of a state in which a silicon wafer is supported on a holder.

FIG. 27 is a sectional view showing a section of the state in which the silicon wafer is supported on the holder illustrated in FIG. 26.

A counterbore or depressed portion having a slightly larger diameter than the diameter of a silicon wafer 200 is formed on a holder 210 (which is also referred to as a susceptor) to be a support member for the silicon wafer 200. The silicon wafer 200 is mounted to be accommodated in the counterbore. In such a state, the holder 210 is rotated to rotate the silicon wafer 200 so that a silicon epitaxial film is grown by the thermal decomposition or hydrogen reduction of the raw gas thus supplied.

When the silicon wafer 200 is mounted on the holder 210 provided with the counterbore having a slightly larger diameter than the diameter of the silicon wafer 200 and they are rotated, the silicon wafer 200 is moved in a horizontal direction substantially parallel to a wafer plane by a centrifugal force thereof and approaches a part of a side surface of the counterbore. In the case in which a silicon epitaxial film having a thickness of several tens μm or more, for example, 50 μm or more which is required for manufacturing the power semiconductor such as an IGBT is to be formed, there is a problem in that the following phenomenon is generated in the holder 210. More specifically, the silicon epitaxial film grown on the side surface portion of the silicon wafer 200 is stuck (bonded) in contact with a film deposited on the side surface of the counterbore of the holder 210 so that the silicon wafer 200 is stuck to the holder 210 when the silicon wafer 200 is to be delivered. In the worst case, there is a problem in that the silicon wafer 200 is broken when the silicon wafer 200 is taken out for delivery.

### BRIEF SUMMARY OF THE INVENTION

Embodiments consistent with the present invention overcome one or more of the above-described problems and disadvantages of the related art.

In accordance with embodiments consistent with the present invention, there is provided a vapor phase deposition apparatus which includes a chamber, a support table disposed in the chamber and adapted to support a substrate in the chamber, a first passage connected to the chamber and adapted to supply gas to the chamber to form a film on the substrate, and a second passage connected to the chamber and adapted to discharge the gas from the chamber. The support table includes a first depressed portion and a second depressed portion formed in a bottom part of the first depressed portion, a bottom face of the second depressed portion for supporting the substrate.

Also in accordance with embodiments consistent with the present invention, the substrate is a wafer, and the second depressed portion is formed in a central portion of the bottom part of the first depressed portion, a depth of the second depressed portion being smaller than a half of a thickness of the wafer.

In accordance with embodiments consistent with the present invention, the support table is rotatable and the substrate is constrained by a sidewall of the first depressed portion to remain within the first depressed portion during rotation.

In accordance with embodiments consistent with the present invention, a vapor phase deposition apparatus includes a chamber, a support table disposed in the chamber and adapted to support a wafer in the chamber, a first passage connected to the chamber and adapted to supply gas to form a film on the wafer, and a second passage connected to the chamber and adapted to discharge the gas from the chamber. The support table is provided with a depressed portion having a depth smaller than a thickness of the wafer.

In accordance with embodiments consistent with the present invention, the depth of the depressed portion is smaller than a half of the thickness of the wafer, and the support table further includes a plurality of pins disposed outside an edge of the depressed portion.

In accordance with embodiments consistent with the present invention, the depth of the depressed portion is set so that a flow of a gas from the first passage over the substrate is caused to be uniform.

In accordance with embodiments consistent with the present invention, a vapor phase deposition apparatus includes a chamber, a support table disposed in the chamber and adapted to support a wafer in the chamber, a first passage connected to the chamber and adapted to supply gas to the chamber to form a film on the wafer, and a second passage connected to the chamber and adapted to discharge the gas from the chamber. The support table includes a first depressed portion and a second depressed portion formed in a bottom part of the first depressed portion, a depth of the second depressed portion being smaller than a thickness of the wafer.

In accordance with embodiments consistent with the present invention, a vapor phase deposition method using a vapor phase deposition apparatus which has a chamber in which a substrate is mounted on a support table, a first passage is accommodated in the chamber to supply gas to form a film, and a second passage which is connected to the chamber and adapted to discharge the gas. The method includes rotating the support table provided with a first depressed portion and a second depressed portion formed in a bottom part of the first depressed portion, while supporting the substrate on a bottom face portion of the second depressed portion of the support table; and supplying, through the first passage, the gas which forms a film to carry out an epitaxial growth in a state in which the substrate is supported.

In accordance with embodiments consistent with the present invention, a vapor phase deposition method using a vapor phase deposition apparatus which has a chamber in which a wafer is mounted on a support table is accommodated in the chamber, a first passage is connected to the chamber and adapted to supply gas to form a film, and a second passage is connected to the chamber and adapted to discharge the gas. The method includes rotating the support table with a depressed portion having a depth smaller than a half of a thickness of the wafer, while supporting the wafer on a bottom face portion of the depressed portion of the support table; and supplying, through the first passage, the gas which forms a film to carry out an epitaxial growth in a state in which the wafer is supported.

In accordance with embodiments consistent with the present invention, the vapor phase deposition method further includes disposing a plurality of pins disposed outside an edge of the depressed portion.

In accordance with embodiments consistent with the present invention, in the vapor phase deposition method, the substrate is a wafer; and the method further includes setting a depth of the second depressed portion is to be smaller than a thickness of the wafer.

In accordance with embodiments consistent with the present invention, the vapor phase deposition method further includes setting the depth of the second depressed portion so that a sum of a depth of the first depressed portion and the depth of the second depressed portion is smaller than the thickness of the wafer.

### BRIEF DESCRIPTION OF THE DRAWINGS

FIG. 1 is a conceptual view showing a structure of an epitaxial deposition apparatus according to a first embodiment,

FIG. 2 is a view showing an example of an appearance of an epitaxial deposition apparatus system,

FIG. 3 is a view showing an example of a unit structure of the epitaxial deposition apparatus system,

FIG. 4 is a top view showing an example of a state in which a silicon wafer is supported on a holder,

FIG. 5 is a sectional view showing a section of the state in which the silicon wafer is supported on the holder illustrated in FIG. 4,

FIG. 6 is a sectional view showing an outer peripheral portion of the silicon wafer and first and second counterbores,

FIG. 7 is a view for explaining a state brought after the formation of a film in the case in which a holder having no two-step counterbore formed thereon is used,

FIG. 8 is a view for explaining a state brought after the formation of a film in the case in which a holder having the two-step counterbore formed thereon according to the present invention is used,

FIG. 9 is a top view showing another example of the state in which the silicon wafer is supported on the holder,

FIG. 10 is a sectional view showing a section of the state in which the silicon wafer is supported on the holder illustrated in FIG. 9,

FIG. 11 is a top view showing yet another example of the state in which the silicon wafer is supported on the holder according to another embodiment,

FIG. 12 is a sectional view showing a section of the state in which the silicon wafer is supported on the holder illustrated in FIG. 11,

FIG. 13 is a sectional view showing an outer peripheral portion of the silicon wafer in FIG. 11 and the first and second counterbores which are enlarged,

FIG. 14 is a chart showing a relationship between a thickness of the silicon wafer in FIG. 13 and a depth of the counterbore,

FIG. 15 is a top view showing a variant of the embodiment in FIG. 11,

FIG. 16 is a sectional view showing a section of a state in which a silicon wafer is supported on a holder illustrated in FIG. 15,

FIG. 17 is a top view showing yet another example of the state in which the silicon wafer is supported on the holder according to a third embodiment,

FIG. 18 is a sectional view showing a section of the state in which the silicon wafer is supported on the holder illustrated in FIG. 8,

FIG. 19 is a sectional view showing an outer peripheral portion of the silicon wafer in FIG. 11 and the first and second counterbores which are enlarged,

FIG. 20 is a top view showing yet another example of the state in which the silicon wafer is supported on the holder according to a fourth embodiment,

FIG. 21 is a sectional view showing a section of the state in which the silicon wafer is supported on the holder illustrated in FIG. 8,

FIG. 22 is a sectional view showing an outer peripheral portion of the silicon wafer in FIG. 11 and the first and second counterbores which are enlarged,

FIG. 23 is a top view showing yet another example of the state in which the silicon wafer is supported on the holder,

FIG. 24 is a sectional view showing a section of the state in which the silicon wafer is supported on the holder illustrated in FIG. 8,

FIG. 25 is a sectional view showing an outer peripheral portion of the silicon wafer in FIG. 11 and the first and second counterbores which are enlarged,

FIG. 26 is a top view showing yet another example of the state in which the silicon wafer is supported on the holder in accordance with the related art, and

FIG. 27 is a sectional view showing a section of the state in which the silicon wafer is supported on the holder in accordance with the related art illustrated in FIG. 26.

### DETAILED DESCRIPTION OF THE INVENTION

### First Embodiment

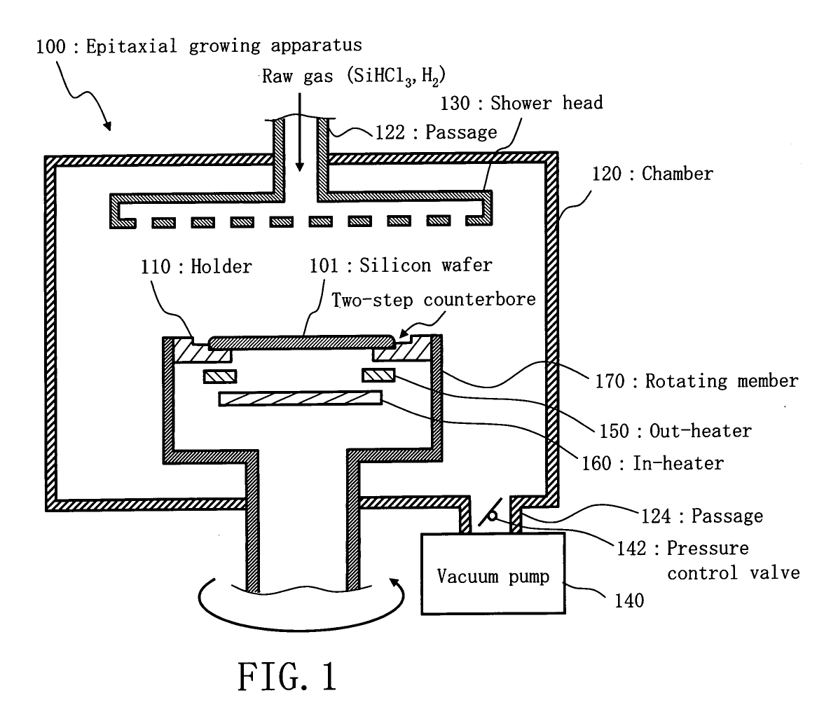

FIG. 1 is a conceptual view showing a structure of an epitaxial deposition apparatus according to a first embodiment.

In FIG. 1, an epitaxial deposition apparatus 100 according to an example of a vapor phase deposition apparatus includes a holder (which will also be referred to as a susceptor) 110 according to an example of a support table, a chamber 120, a shower head 130, a vacuum pump 140, a pressure control valve 142, an out-heater 150, an in-heater 160 and a rotating member 170. A passage 122 which supplies a gas and a passage 124 which discharges the gas are connected to the chamber 120. The passage 122 is connected to the shower head 130. In FIG. 1, necessary structures for explaining the first embodiment are illustrated. The epitaxial deposition apparatus 100 may be provided with portions other than structures in FIG. 1. Moreover, a contraction scale or the like is not coincident with a real object (This applies to other drawings also).

A holder 110 has an outer periphery formed circularly and is provided with an opening portion to penetrate through a predetermined inside diameter. There are formed a first counterbore according to an example of a first depressed portion dug in a first depth from an upper surface of the holder 110 and a second counterbore according to an example of a second depressed portion dug in a second depth from a bottom face of the first depressed portion and having a smaller diameter than a diameter of the first depressed portion. The silicon wafer 101 is supported in contact with the back face of the silicon wafer 101 according to an example of the substrate at a bottom face of the second counterbore.

The holder 110 is disposed on the rotating member 170 to be rotated around a centerline of the silicon wafer 101 plane which is orthogonal to the silicon wafer 101 plane by means of a rotating mechanism which is not shown. The holder 110 is rotated together with the rotating member 170 so that the silicon wafer 101 can be rotated.

The out-heater 150 and the in-heater 160 are disposed on the back side of the holder 110. It is possible to heat the outer peripheral portion of the silicon wafer 101 and the holder 110 by means of the out-heater 150. The in-heater 160 is disposed under the out-heater 150 and portions other than the outer peripheral portion of the silicon wafer 101 can be heated by means of the in-heater 160. In addition to the in-heater 160, the out-heater 150 is provided for heating the outer peripheral portion of the silicon wafer 101 from which a heat is easily radiated to the holder 110. By thus constituting a double heater, it is possible to enhance an in-plane uniformity of the silicon wafer 101.

The holder 110, the out-heater 150, the in-heater 160, the shower head 130 and the rotating member 170 are disposed in the chamber 120. The rotating member 170 is extended from the inside of the chamber 120 to the rotating mechanism (not shown) on the outside of the chamber 120. A pipe of the shower head 130 is extended from the inside of the chamber 120 to the outside of the chamber 120.

In a state in which the inside of the chamber 120 to be a reactor is held at an atmospheric pressure or in the vacuum having a predetermined degree of vacuum by means of the vacuum pump 140, the silicon wafer 101 is heated by means of the out-heater 150 and the in-heater 160 and a raw gas to be a silicon source is supplied from the shower head 130 into the chamber 120 while the silicon wafer 101 is rotated at a predetermined rotating speed by the rotation of the holder 110. The thermal decomposition or hydrogen reduction of the raw gas is carried out over the surface of the heated silicon wafer 101 to grow a silicon epitaxial film on the surface of the silicon wafer 101. A pressure in the chamber 120 may be regulated into the atmospheric pressure or the vacuum having a predetermined degree of vacuum by means of the pressure control valve 142. In the case in which the atmospheric pressure is used, alternatively, it is also possible to employ a structure in which the vacuum pump 140 or the pressure control valve 142 is not provided. In the shower head 130, the raw gas supplied from the outside of the chamber 120 through the pipe is discharged from a plurality of through holes via a buffer in the shower head 130. Therefore, the raw gas can be uniformly supplied onto the silicon wafer 101. By setting the pressures of the holder 110 and the rotating member 170 to be equal to each other on the inside and the outside (setting a pressure in an atmosphere on the surface side of the silicon wafer 101 and a pressure in an atmosphere on the back side thereof to be equal to each other), it is possible to prevent the raw gas from going around the inside of the rotating member 170 or the inside of the rotating mechanism. Similarly, it is possible to prevent a purge gas on the rotating mechanism side (not shown) or the like from leaking into the chamber (the atmosphere on the surface side of the silicon wafer 101).

For example, 34 Pa·m³/s (20 SLM) of a gas obtained by diluting trichlorosilane (SiHCl₃) with hydrogen (H₂) into 25% and 85 Pa·m³/s (50 SLM) of H₂ are supplied respectively as a silicon source and a carrier gas from the shower head 130. More specifically, a concentration of the SiHCl₃ in the whole gas is set to be 7.2%. Then, the in-heater 160 is set to be 1100° C. and the out-heater 150 is set to be 1098° C. Moreover, a rotating speed of the silicon wafer is set to be 500 to 1500 min⁻¹ (500 to 1500 rpm). An in-chamber pressure is set to be 9.3×10⁴ Pa (700 Torr). By the process conditions, it is possible to form a silicon epitaxial film having a thickness of several tens μm or more, for example, 50 μm or more which is required for manufacturing a power semiconductor such as an IGBT.

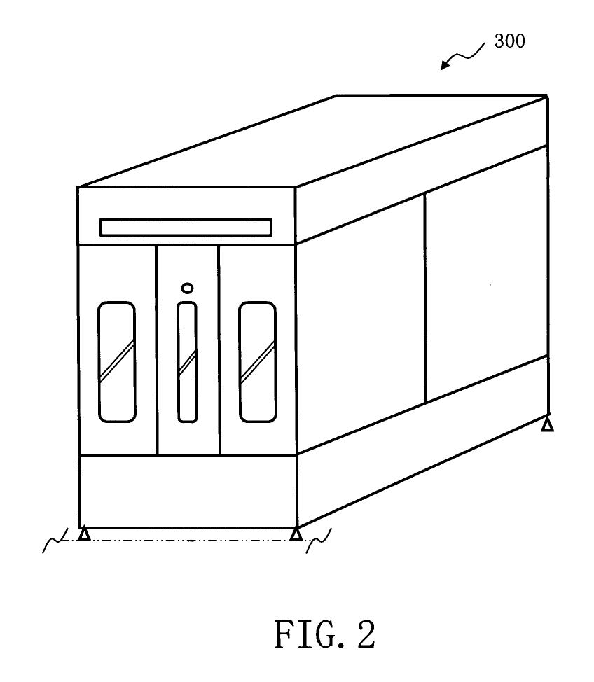

FIG. 2 is a view showing an example of an appearance of the epitaxial deposition apparatus system.

As shown in FIG. 2, an epitaxial deposition apparatus system 300 is wholly surrounded by a housing.

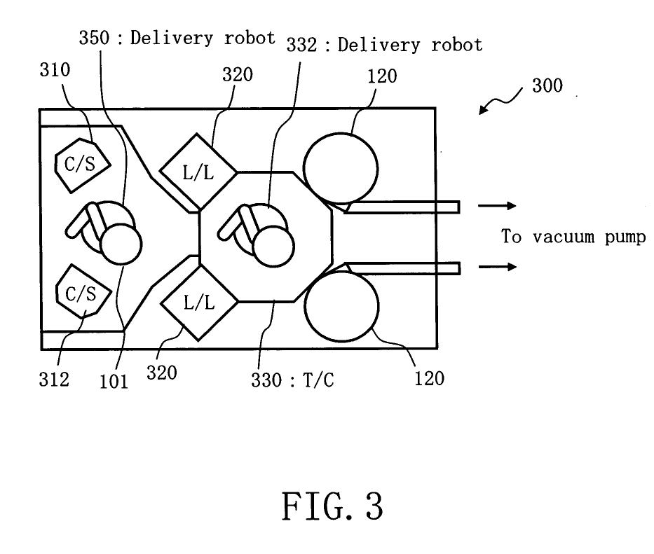

FIG. 3 is a view showing an example of a unit structure of the epitaxial growth apparatus system.

In the epitaxial growth apparatus system 300, the silicon wafer 101 set into a cassette disposed in a cassette stage (C/S) 310 or a cassette stage (C/S) 312 is delivered into a load lock (UL) chamber 320 by means of a transfer robot 350. Then, the silicon wafer 101 is delivered from the UL chamber 320 into a transfer chamber 330 by means of a delivery robot 332 disposed in the transfer chamber 330. The delivered silicon wafer 101 is delivered into the chamber 120 of the epitaxial growth apparatus 100 and a silicon epitaxial film is formed on the surface of the silicon wafer 101 by an epitaxial growth method. The silicon wafer 101 on which the silicon epitaxial film is formed is delivered again from the epitaxial growth apparatus 100 into the transfer chamber 330 by means of the delivery robot 332. The delivered silicon wafer 101 is delivered to the UL chamber 320 and is then returned from the UL chamber 320 to the cassette disposed in the cassette stage (C/S) 310 or the cassette stage (C/S) 312 by means of the delivery robot 350. In the epitaxial deposition apparatus system 300 shown in FIG. 3, two chambers 120 and two UL chambers 320 in the epitaxial deposition apparatus 100 are mounted so that a throughput can be enhanced.

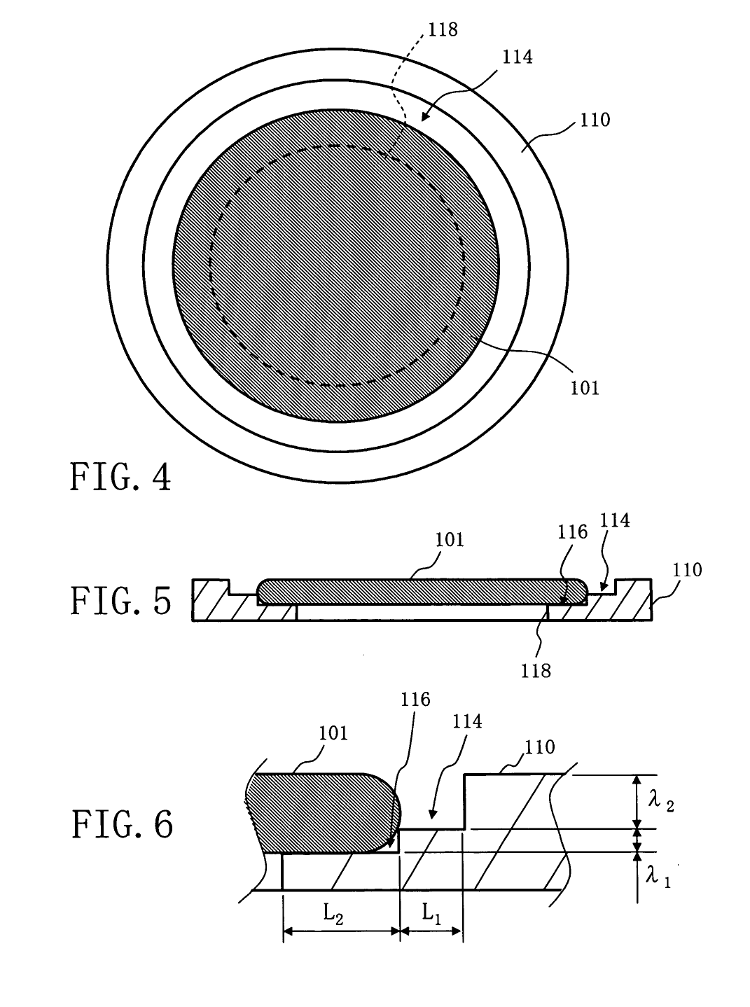

FIG. 4 is a top view showing an example of a state in which the silicon wafer is supported on the holder.

FIG. 5 is a sectional view showing a section of the state in which the silicon wafer is supported on the holder illustrated in FIG. 4.

A two-step depressed portion is formed on the holder 110. More specifically, a first depressed portion 114 has a depth which is a little more than a half of a thickness of the silicon wafer 101 and is formed to have a larger diameter than the diameter of the silicon wafer 101. A second depressed portion 116 is formed on the bottom face of the first depressed portion 114 with a depth which is smaller than a half of the thickness of the silicon wafer 101 and a diameter which is slightly larger than the diameter of the silicon wafer 101 and smaller than the diameter of the first depressed portion 114. The silicon wafer 101 is supported on the bottom face of the second depressed portion 116. More particularly, an inner periphery 118 of the second depressed portion 116 extends beneath the silicon wafer 101 to support the silicon wafer 101. In the case in which the holder 110 is rotated so that the silicon wafer 101 is moved in a parallel direction with the silicon wafer surface by a centrifugal force thereof, an upper end of the side surface of the second depressed portion 116 abuts on a face in a lower part of a bevel portion of the outer peripheral portion of the silicon wafer 101 so that the silicon wafer 101 can be prevented from slipping off. If the silicon wafer 101 is moved beyond the upper end of the side surface of the second depressed portion 116, the side surface of the first depressed portion 114 abuts on the side surface of the silicon wafer 101 so that the silicon wafer 101 can be prevented from slipping off.

It is preferable that the bottom face of the second depressed portion 116 is subjected to a nonslip processing. By carrying out the nonslip processing over the bottom face of the second counterbore 116, it is possible to increase a frictional force of the back face of the silicon wafer 101 and the bottom face of the second depressed portion 116. Examples include a blast treatment. Alternatively, it is preferable that the bottom face is formed like teeth of a file. By increasing the frictional force of the back face of the silicon wafer 101 and the bottom face of the second depressed portion 116, it is possible to suppress the silicon wafer 101 from slipping out of the holder 110.

FIG. 6 is a sectional view showing the outer peripheral portion of the silicon wafer and the first and second depressed portions.

As shown in FIG. 6, it is desirable that a depth λ1 of the second depressed portion 116 is set in such a manner that the height of the bottom face of the first depressed portion 114 is positioned on the lower surface side of the bevel portion of the silicon wafer 101. For example, it is desirable that the dimension λ1 in FIG. 6 is in the range of 20 to 40% of the thickness of the silicon wafer 101. More specifically, in case of a silicon wafer having a diameter of 200 mm, for example, it is desirable that λ1=0.2±0.05 mm is set because the thickness t is 0.725 mm. Moreover, a depth λ2 for digging the first depressed portion 114 is desirably in the range of 50 to 65% of the thickness of the silicon wafer 101. More specifically, in case of the silicon wafer having the diameter of 200 mm, for example, it is desirable that λ2=0.4±0.05 mm is set because the thickness t is 0.725 mm. Furthermore, it is desirable that λ1:λ2≈1:2 is set. It is desirable that a length L2 in a radial direction of the bottom face of the second depressed portion 116 for holding the silicon wafer 101 in contact with a back face thereof is slightly greater than that in the related art, that is, 1 to 4 mm. It is desirable that a length L1 in the radial direction of the bottom face of the second depressed portion 116 is equal to or greater than a double of a thickness of a silicon epitaxial film to be formed on the surface of the silicon wafer 101 with a raw gas. For example, in the case in which a film is formed in a thickness of 120 μm, it is preferable that the length L1 is set to be equal to or greater than 240 μm, that is, 0.24 mm. By forming a film to have a dimension which is equal to or greater than a double of the thickness of a silicon epitaxial film to be formed on the surface of the silicon wafer 101, it is possible to avoid a contact of a film grown on the side surface of the silicon wafer 101 and a film grown on the silicon wafer 101 side from the side surface of the first depressed portion 114. For example, L1 is set to be 1 mm.

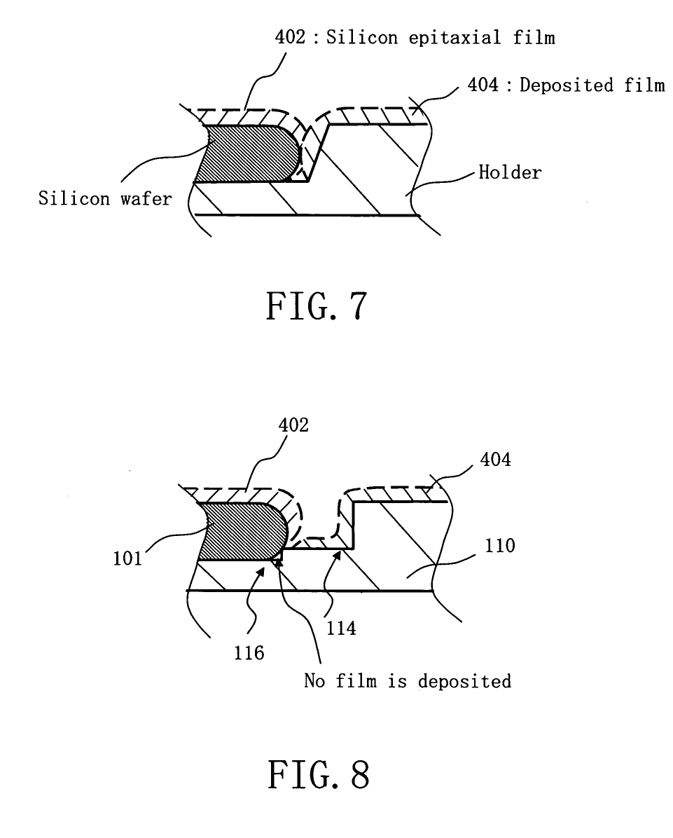

FIG. 7 is a view for explaining a state brought after the formation of a film in the case in which a holder not having a two-step depressed portion formed thereon is used.

FIG. 8 is a view for explaining a state brought after the formation of a film in the case in which a holder having the two-step depressed portion formed thereon according to the present embodiment is used.

In the case in which the holder having no two-step depressed portion formed thereon is used as shown in FIG. 7, the silicon epitaxial film 402 grown in the side surface portion of the silicon wafer and the deposited film 404 on the side surface of the depressed portion of the holder come in contact with each other are stuck (bonded) to each other so that the silicon wafer adheres to the holder. On the other hand, the holder 110 is rotated in the case in which the holder 110 having the two-step depressed portion formed thereon according to the present embodiment is used as shown in FIG. 8, and the upper end of the side surface of the second depressed portion 116 abuts on the surface in the lower part of the bevel portion of the outer peripheral portion of the silicon wafer 101 in the case in which the silicon wafer 101 is moved in a parallel direction with the silicon wafer surface by a centrifugal force thereof. Consequently, the bevel portion serves as a roof so that the deposition of the film 404 can be prevented or lessened. As a result, bonding of the films in the abutting portion can be lessened. Therefore, it is possible to prevent the silicon wafer 101 from being stuck to the holder 110.

Furthermore, a trench surrounded by the side surface of the first depressed portion 114 is formed around the silicon wafer 101 through the first depressed portion 114. By providing the trench, it is possible to reduce the amount of the deposition of the deposited film on the bottom part of the trench.

### Second Embodiment

In the second embodiment, a plurality of pins 112 to be struts is disposed in place of the formation of the first counterbore.

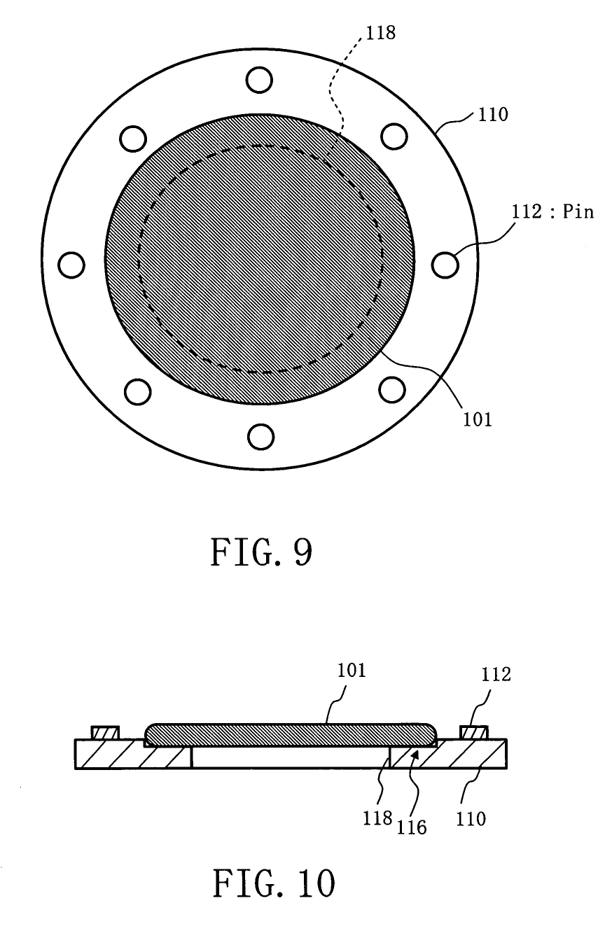

FIG. 9 is a top view showing another example of the state in which the silicon wafer is supported on the holder.

FIG. 10 is a sectional view showing a section of the state in which the silicon wafer is supported on the holder illustrated in FIG. 9.

A holder 110 is provided with a second depressed portion 116 having a slightly larger diameter than a diameter of a silicon wafer 101 and dug to have a depth which is smaller than a half of a thickness of the silicon wafer 101. The silicon wafer 101 is supported on a bottom face of the second depressed portion 116. At least three pins 112 are uniformly disposed with a predetermined clearance provided from the outer periphery of the silicon waver 101 over an upper surface of a holder 110. More specifically, the pins 112 are disposed on the outside of the second depressed portion 116. In FIG. 9, eight pins 112 are disposed uniformly as an example. In the case in which the holder 110 is rotated so that the silicon wafer 101 is moved in a parallel direction with the silicon wafer surface by a centrifugal force thereof, an upper end of a side surface of the second depressed portion 116 abuts on a surface in a lower part of a bevel portion of an outer peripheral portion of the silicon wafer 101 so that the silicon wafer 101 can be suppressed from slipping off. If the silicon wafer 101 is moved beyond the upper end of the side surface of the second depressed portion 116, the side surface of the silicon wafer 101 abuts on some of the three pins 112 or more (herein, eight pins 112). Consequently, the silicon wafer 101 can be prevented from slipping off.

In the case in which the holder 110 is rotated so that the silicon wafer 101 is moved in a parallel direction with the silicon wafer surface by the centrifugal force thereof, the upper end of the side surface of the second depressed portion 116 abuts on the surface in the lower part of the bevel portion of the outer peripheral portion of the silicon wafer 101. Consequently, the bevel portion serves as a roof so that the deposition of a deposited film can be prevented. This respect is the same as that in the first embodiment. Accordingly, the films are not bonded to each other in the abutting portion. Consequently, it is possible to prevent the silicon wafer 101 from being stuck to the holder 110.

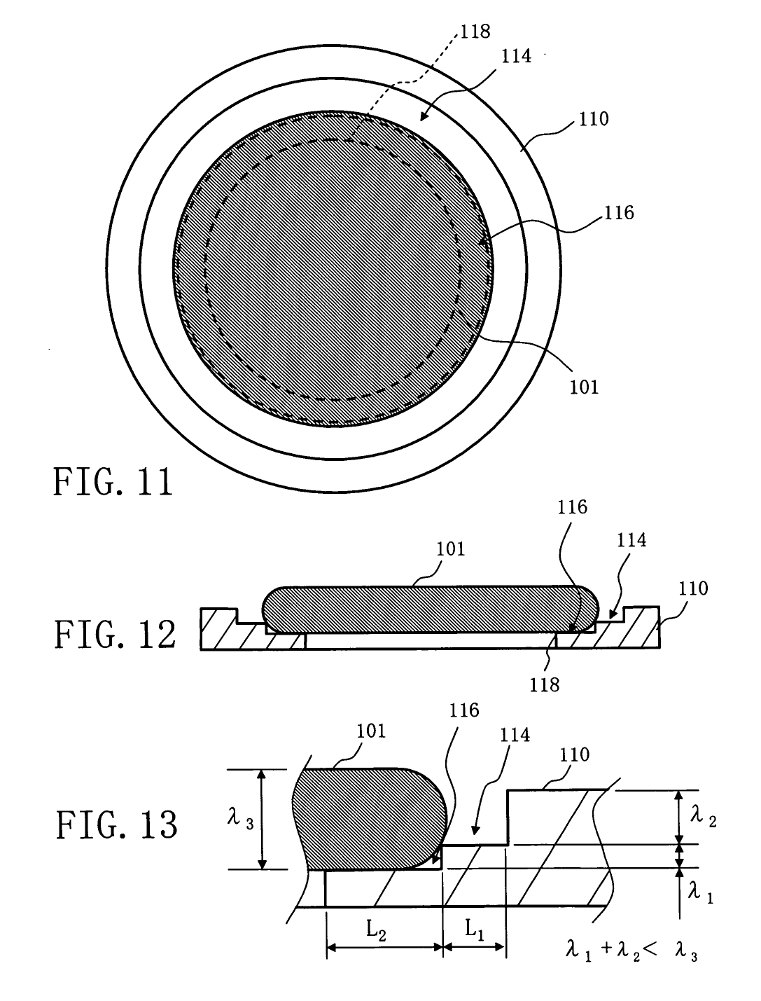

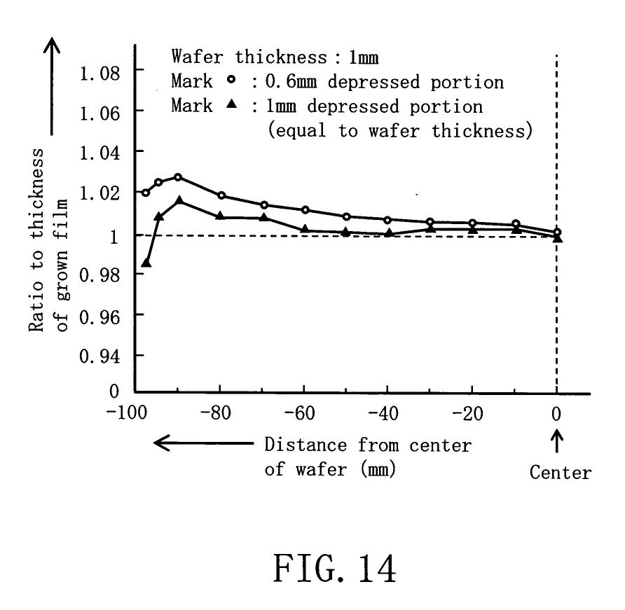

Although the relationship between the depths of the two depressed portions 114 and 116 and the thickness of the silicon wafer 101 has not been described in detail in the embodiments, it is desirable that the thickness of the silicon wafer 101 is set to be greater than a depth obtained by adding the depths of the first depressed portion 114 and the second depressed portion 116 as shown in FIGS. 11 to 13 (a relationship of λ1+λ2<λ3 in FIG. 13). For example, in the case in which the silicon wafer 101 has a thickness of 1 mm, a flow of a gas to be supplied becomes smooth if the depth obtained by adding the thicknesses of the first depressed portion 114 and the second depressed portion 116 is set to be 0.6 mm. Consequently, a thickness obtained after the formation of the film is also uniform comparatively up to an end as shown in FIG. 14. In FIG. 14, if the depth obtained by adding the depths of the first depressed portion 114 and the second depressed portion 116 is set to be 1 mm which is equal to the thickness of the wafer, a considerable change in the thickness of the film is generated on the edge part of the wafer, resulting in a reduction in a area in which wafer can be utilized.

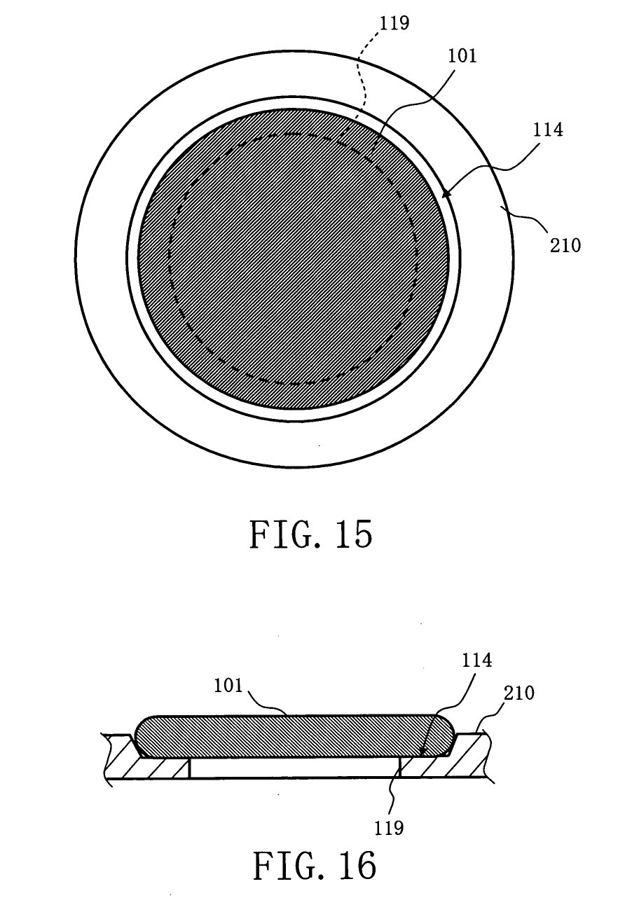

While the two-step depressed portion has been described in the embodiments, moreover, the same advantages as those in the embodiments can be obtained if the depth of the depressed portion is smaller than the thickness of the wafer also in FIGS. 15 and 16. Also in this case, the depth of the depressed portion is approximately 0.6 mm. As seen in FIGS. 15 and 16, an inner periphery 119 of the first depressed portion 114 extends beneath the silicon wafer 101 to support the silicon wafer 101.

It is desirable that the depth of the first depressed portion or the depth obtained by adding the depths of the first depressed portion and the second depressed portion is 70% to 95% of the thickness of the substrate.

### Third Embodiment

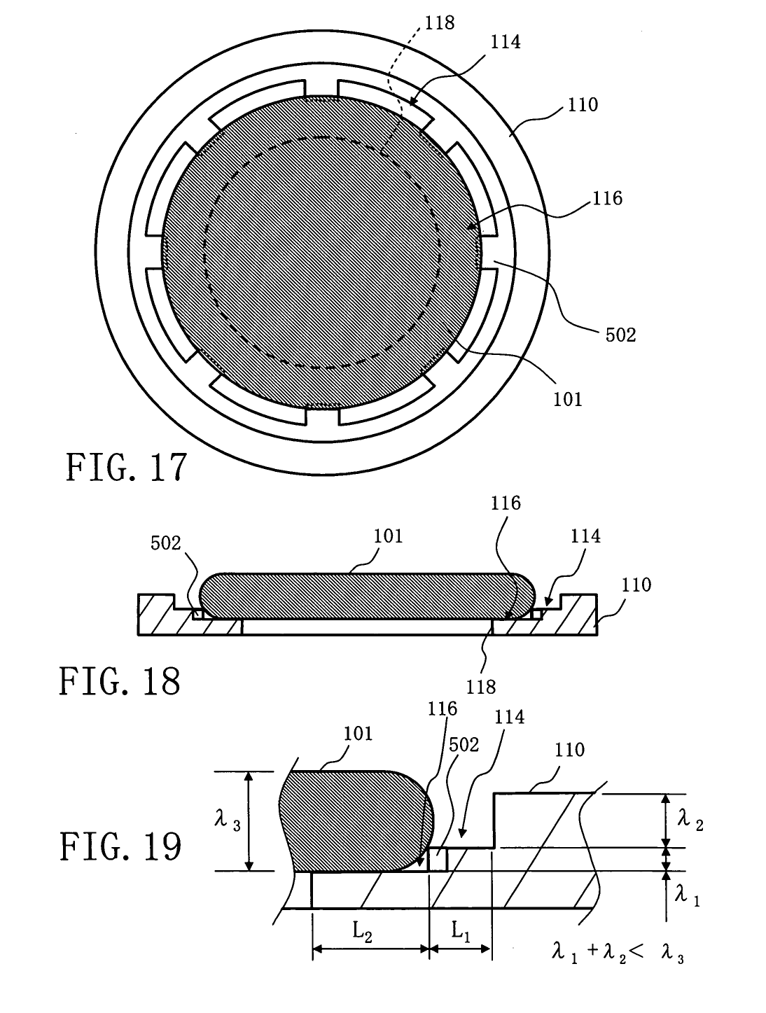

FIG. 17 is a top view showing an example of a state in which a silicon wafer is supported on a holder according to a third embodiment.

FIG. 18 is a sectional view showing a section of the state in which the silicon wafer is supported on the holder illustrated in FIG. 17.

FIG. 19 is a sectional view showing an outer peripheral portion of the silicon wafer and first and second depressed portions in FIG. 17 which are enlarged.

In the third embodiment, a plurality of projecting portions 502 extended in a direction of a center of a silicon wafer 101 from a side surface of the depressed portion 116 to be a second depressed portion is provided as shown in FIGS. 17 to 19 for the holder 110 shown in FIGS. 4 to 6 according to the first embodiment or FIGS. 11 to 13 according to the second embodiment. Others are the same as those in the first embodiment or the second embodiment. A tip part of the projecting portion 502 is formed to be a plane. By providing the projecting portion 502, it is possible to reduce a contact area with the silicon wafer 101 more. As a result, bonding between the films can be lessened. Therefore, it is possible to reduce the sticking of the silicon wafer 101 to the holder 110 more.

### Fourth Embodiment

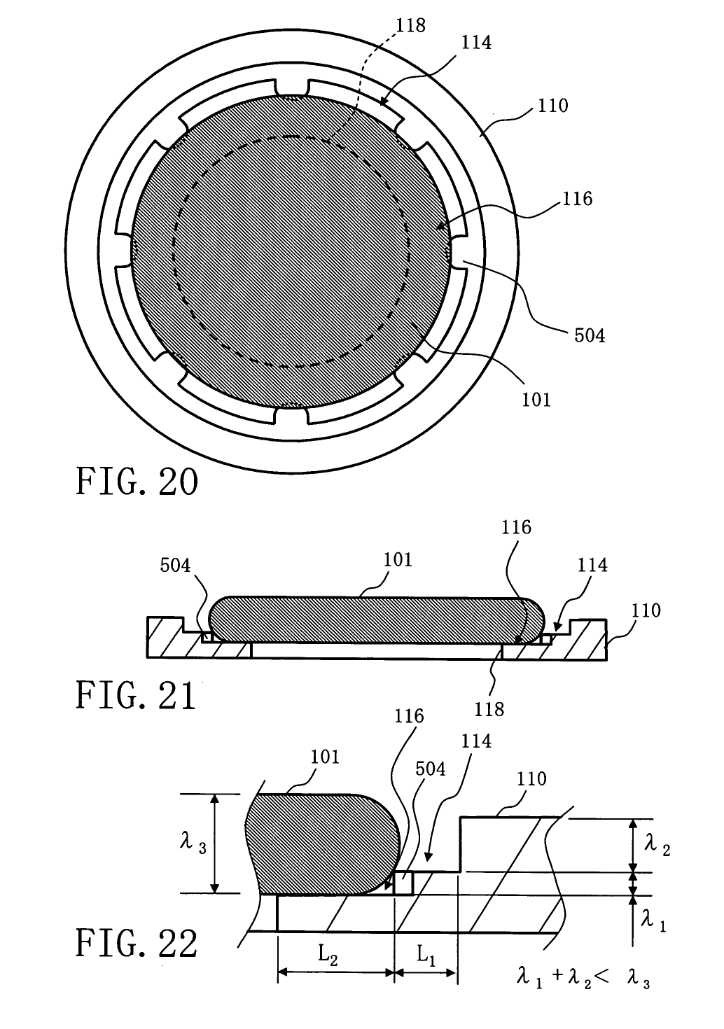

FIG. 20 is a top view showing an example of a state in which a silicon wafer is supported on a holder according to a fourth embodiment.

FIG. 21 is a sectional view showing a section of the state in which the silicon wafer is supported on the holder illustrated in FIG. 20.

FIG. 22 is a sectional view showing an outer peripheral portion of the silicon wafer and first and second counterbores in FIG. 20 which are enlarged.

In the fourth embodiment, a plurality of projecting portions 504 extended in a direction of a center of a silicon wafer 101 from a side surface of the depressed portion 116 is provided as shown in FIGS. 20 to 22 for the holder 110 shown in FIGS. 4 to 6 according to the first embodiment or FIGS. 11 to 13 according to the second embodiment. Others are the same as those in the first embodiment or the second embodiment. A tip part of the projecting portion 504 is formed to be a round shaped surface as seen from above. By providing the projecting portion 504, it is possible to cause a contact with the silicon wafer 101 to be a line contact or a point contact, thereby reducing a contact area more. As a result, bonding between the films can be lessened. Therefore, it is possible to reduce the sticking of the silicon wafer 101 to the holder 110 more.

### Fifth Embodiment

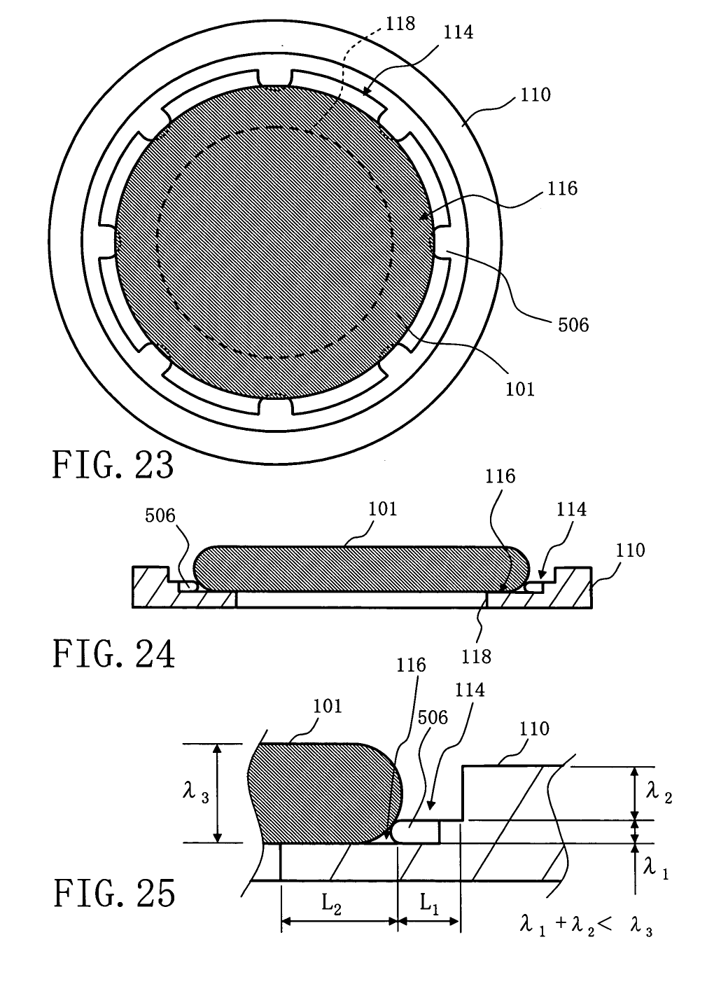

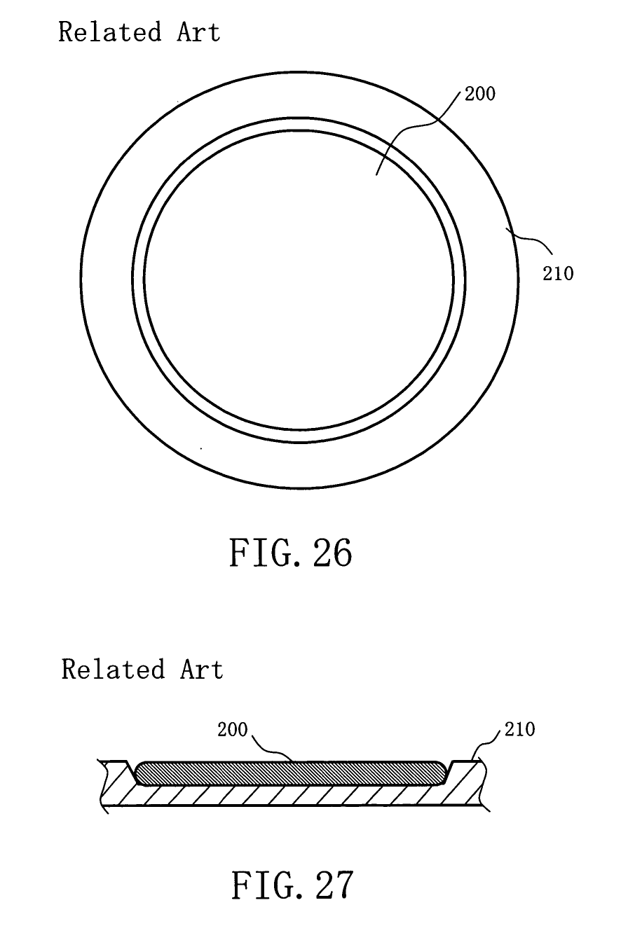

FIG. 23 is a top view showing an example of a state in which a silicon wafer is supported on a holder according to a fifth embodiment.

FIG. 24 is a sectional view showing a section of the state in which the silicon wafer is supported on the holder illustrated in FIG. 23.

FIG. 25 is a sectional view showing an outer peripheral portion of the silicon wafer and first and second counterbores in FIG. 23 which are enlarged.

In the fifth embodiment, a plurality of projecting portions 506 extended in a direction of a center of a silicon wafer 101 from a side surface of the depressed portion 116 is provided as shown in FIGS. 23 to 25 for the holder 110 shown in FIGS. 4 to 6 according to the first embodiment or FIGS. 11 to 13 according to the second embodiment. Others are the same as those in the first embodiment or the second embodiment. A tip part of the projecting portion 506 is formed to be a spherical curved surface. By providing the projecting portion 506, it is possible to cause a contact with the silicon wafer 101 to be a point contact, thereby reducing a contact area more. As a result, bonding between the films can be lessened. Therefore, it is possible to reduce the sticking of the silicon wafer 101 to the holder 110 more.

As described above, in the vapor phase deposition apparatus according to an aspect of the present invention in which a substrate mounted on a support table is accommodated in a chamber, and a first passage which supplies a gas to form a film and a second passage which discharges the gas are connected to the chamber, the support table includes a first depressed portion and a second depressed portion formed in a bottom part of the first depressed portion.

By such a structure, also in the case in which the substrate is provided beyond the side surface of the second depressed portion, it is possible to prevent the substrate from jumping outside of the support portion over the side surface of the first depressed portion. By forming the trench through the first depressed portion around the substrate, furthermore, it is possible to reduce the thickness of the deposited film deposited on the bottom face of the trench to be the bottom face of the first depressed portion.

The second depressed portion is formed in a central portion of the bottom part of the first depressed portion and a depth thereof is smaller than a half of a thickness of the substrate.

The substrate is supported on the bottom face of the second depressed portion which has a depth smaller than a half of the thickness of the substrate. Also in the case in which the substrate is moved in the same direction as the substrate surface to approach in a certain direction, consequently, the upper part of the side surface of the second depressed portion can be caused to come in contact with the substrate in the lower part of the bevel portion of the substrate. As a result, the bevel portion of the substrate serves as a roof. Thus, it is possible to prevent or lessen the deposition of the deposited film in the contact portion.

In other words, a side part of the second depressed portion is parallel or makes an acute angle with respect to a direction of a depth, and has a portion in which a film is not formed together with a part of a side surface of the substrate.

It is preferable that the second depressed portion is formed in a central portion of the bottom part of the first depressed portion and a depth thereof is equal to or greater than 20% and is equal to or smaller than 40% of a thickness of the substrate.

When the support table is rotated, the substrate is supported so as not to jump outside the first depressed portion.

As described above, in a vapor phase deposition apparatus according to another aspect of the present invention in which a substrate mounted on a support table is accommodated in a chamber, and a first passage which supplies a gas to form a film and a second passage which discharges the gas are connected to the chamber, the support table is provided with a first depressed portion and a depth of the first depressed portion is set to be smaller than a thickness of the substrate.

By such a structure, that is, a structure in which the depth of the first depressed portion is set to be smaller than the thickness of the substrate, the flow of the gas over the substrate can be uniform, and furthermore, the thickness of the grown film can be almost uniform.

As described above, in a vapor phase deposition apparatus according to a further aspect of the present invention in which a substrate mounted on a support table is accommodated in a chamber, and a first passage which supplies a gas to form a film and a second passage which discharges the gas are connected to the chamber, the support table is provided with a first depressed portion and a depth of the first depressed portion is set to be smaller than a thickness of the substrate so that a flow of a gas from the first passage over the substrate is caused to be uniform.

It is desirable that the depth of the first depressed portion is 70% to 95% of the thickness of the substrate.

As described above, in a vapor phase deposition apparatus according to a further aspect of the present invention in which a substrate mounted on a support table is accommodated in a chamber, and a first passage which supplies a gas to form a film and a second passage which discharges the gas are connected to the chamber, the support table includes a first depressed portion and a second depressed portion formed in a bottom part of the first depressed portion, and a depth of the second depressed portion is set to be smaller than a thickness of the substrate.

By such a structure, even if the substrate is provided beyond the side surface of the second depressed portion, it is possible to prevent the substrate from jumping outside of the support portion over the side surface of the first depressed portion. By forming the trench through the first depressed portion around the substrate, furthermore, it is possible to reduce the thickness of the film deposited on the bottom face of the trench to be the bottom face of the first depressed portion. By setting the depth of the second depressed portion to be smaller than the thickness of the substrate, moreover, it is possible to suppress the flow of the gas over the substrate, and furthermore, to cause the thickness of the grown film to be uniform.

As described above, in a vapor phase deposition apparatus according to a further aspect of the present invention in which a substrate mounted on a support table is accommodated in a chamber, and a first passage which supplies a gas to form a film and a second passage which discharges the gas are connected to the chamber, the support table includes a first depressed portion and a second depressed portion formed in a bottom part of the first depressed portion, and a depth obtained by adding a depth of the first depressed portion and that of the second depressed portion is set to be smaller than a thickness of the substrate.

By such a structure, in the same manner as the respects described above, also in the case in which the substrate is provided beyond the side surface of the second depressed portion, it is possible to prevent the substrate from jumping outside of the support portion over the side surface of the first depressed portion. By forming the trench through the first depressed portion around the substrate, furthermore, it is possible to reduce the thickness of the deposited film deposited on the bottom face of the trench to be the bottom face of the first depressed portion. Moreover, the depth obtained by adding the depth of the first depressed portion and that of the second depressed portion is set to be smaller than the thickness of the substrate. Consequently, the flow of the gas over the substrate can be uniform, and furthermore, the thickness of the grown film can also be uniform (particularly, at an end).

There is provided the projecting portion extended in the direction of the center of the substrate from the side surface of the second depressed portion. Also in the case in which the substrate comes in contact with the side surface of the second depressed portion, consequently, the contact with the projecting portion is made. Therefore, it is possible to decrease the contact area.

As described above, according to the embodiments, it is possible to reduce the thickness of the deposited film deposited on the bottom face of the trench to be the bottom face of the first depressed portion. Therefore, it is possible to reduce the sticking of the substrate to the support portion. Also in the case in which the substrate is moved in the same direction as the substrate surface to approach in a certain direction, furthermore, the bevel portion of the substrate serves as a roof. Consequently, it is possible to prevent or lessen the deposition of the deposited film in the contact portion. Therefore, it is possible to prevent the sticking of the substrate to the support portion. By setting the depth of the first depressed portion to be smaller than the thickness of the substrate, and furthermore, setting the depth obtained by adding the depth of the first depressed portion and that of the second depressed portion to be smaller than the thickness of the substrate, moreover, it is possible to cause the flow of the gas over the substrate to be uniform, and furthermore, to cause the thickness of the grown film to be uniform.

The description has been given to the embodiments with reference to the specific examples. However, the present invention is not limited to these specific examples. For example, while the description has been given to the epitaxial deposition apparatus as an example of the vapor phase deposition apparatus, this is not the only case but it is also possible to use any apparatus for causing a predetermined film to be vapor phase grown on a sample face. For example, it is also possible to use a apparatus for deposition a polysilicon film.

While the portions which are not directly required for the description of the present invention, for example, a structure of the apparatus, a control technique and the like have been omitted, moreover, it is possible to properly select and use the structure of the apparatus and the control technique which are required. For example, although the structure of the control portion for controlling the epitaxial deposition apparatus 100 has not been described, it is obvious that the structure of the control portion to be required is properly selected and used.

All vapor phase deposition apparatuses which comprise the elements according to the present invention and can be properly designed and changed by those skilled in the art and the shape of the support member are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A vapor phase deposition apparatus comprising:
a chamber,
a support table disposed in the chamber and adapted to support a substrate in the chamber,
a first passage connected to the chamber and adapted to supply gas to the chamber to form a film on the substrate, and
a second passage connected to the chamber and adapted to discharge the gas from the chamber,
wherein the support table includes a first depressed portion and a second depressed portion formed in a bottom part of the first depressed portion, a bottom face of the second depressed portion for supporting the substrate.

2. A vapor phase deposition apparatus according to claim 1,
wherein the substrate is a wafer, and
the second depressed portion is formed in a central portion of the bottom part of the first depressed portion, a depth of the second depressed portion being smaller than a half of a thickness of the wafer.

3. A vapor phase deposition apparatus according to claim 1,
wherein the support table is rotatable and the substrate is constrained by a sidewall of the first depressed portion to remain within the first depressed portion during rotation.

4. The vapor phase deposition apparatus according to claim 2, wherein the depth of the second depressed portion lies in a range from equal to or greater than 20% to equal to or smaller than 40% of the thickness of the wafer.

5. The vapor phase deposition apparatus according to claim 2, wherein a sidewall of the second depressed portion is substantially perpendicular to the bottom face of the second depressed portion, such that a side surface of the substrate can abut on the sidewall of the second depressed portion and the abutment can serve as a roof.

6. The vapor phase deposition apparatus according to claim 3, wherein the substrate is a wafer, and
a depth of the first depressed portion is configured to be greater than a half of a thickness of the wafer.

7. The vapor phase deposition apparatus according to claim 1, wherein the bottom face of the second depressed portion is subjected to a nonslip processing.

8. The vapor phase deposition apparatus according to claim 7, wherein a blast treatment is carried out as the nonslip processing.

9. The vapor phase deposition apparatus according to claim 1, wherein the support table is provided with a projection extended in a direction toward a center of the second depressed portion from a side surface of the second depressed portion.

10. The vapor phase deposition apparatus according to claim 9, wherein the projection is formed with a substantially planar tip part.

11. The vapor phase deposition apparatus according to claim 9, wherein the projection is formed with a round shaped tip part.

12. The vapor phase deposition apparatus according to claim 9, wherein the projection is formed with a spherical tip part.

13. A vapor phase deposition apparatus comprising:
a chamber,
a support table disposed in the chamber and adapted to support a wafer in the chamber,
a first passage connected to the chamber and adapted to supply gas to form a film on the wafer, and
a second passage connected to the chamber and adapted to discharge the gas from the chamber,
wherein the support table is provided with a depressed portion having a depth smaller than a thickness of the wafer.

14. A vapor phase growing apparatus according to claim 13,
wherein the depth of the depressed portion is smaller than a half of the thickness of the wafer, and the support table further includes a plurality of pins disposed outside an edge of the depressed portion.

15. The vapor phase deposition apparatus according to claim 13, wherein the depth of the depressed portion is 70% to 95% of the thickness of the wafer.

16. A vapor phase deposition apparatus according to claim 13,
wherein the depth of the depressed portion is set so that a flow of gas from the first passage over the wafer is caused to be uniform.

17. The vapor phase deposition apparatus according to claim 16, wherein the depth of the depressed portion is 70% to 95% of the thickness of the wafer.

18. A vapor phase deposition apparatus comprising:
a chamber,
a support table disposed in the chamber and adapted to support a wafer in the chamber,
a first passage connected to the chamber and adapted to supply gas to the chamber to form a film on the wafer, and
a second passage connected to the chamber and adapted to discharge the gas from the chamber,
wherein the support table includes a first depressed portion and a second depressed portion formed in a bottom part of the first depressed portion, a depth of the second depressed portion being smaller than a thickness of the wafer.

19. The vapor phase deposition apparatus according to claim 18, wherein the support table is provided with a projection extended in a direction toward a center of the second depressed portion from a side surface of the second depressed portion.

20. A vapor phase deposition apparatus according to claim 18,
wherein a sum of a depth of the first depressed portion and the depth of the second depressed portion is smaller than the thickness of the wafer.

21. The vapor phase deposition apparatus according to claim 20, wherein the support table is provided with a projection extended in a direction toward a center of the second depressed portion from a side surface of the second depressed portion.

22. A vapor phase deposition method using a vapor phase deposition apparatus which has a chamber in which a substrate is mounted on a support table, a first passage is connected to the chamber and adapted to supply gas to form a film, and a second passage is connected to the chamber and adapted to discharge the gas, comprising:
rotating the support table provided with a first depressed portion and a second depressed portion formed in a bottom part of the first depressed portion, while supporting the substrate on a bottom face portion of the second depressed portion of the support table; and
supplying, through the first passage, the gas which forms a film to carry out an epitaxial growth in a state in which the substrate is supported.

23. A vapor phase deposition method using a vapor phase deposition apparatus which has a chamber in which a wafer is mounted on a support table, a first passage is connected to the chamber and adapted to supply gas to form a film, and a second passage is connected to the chamber and adapted to discharge the gas, comprising:
rotating the support table with a depressed portion having a depth smaller than a half of a thickness of the wafer, while supporting the wafer on a bottom face portion of the depressed portion of the support table; and
supplying, through the first passage, the gas which forms a film to carry out an epitaxial growth in a state in which the wafer is supported.

24. A vapor phase deposition method according to claim 23, further including:
disposing a plurality of pins disposed outside an edge of the depressed portion.

25. A vapor phase deposition method according to claim 22, wherein
the substrate is a wafer;
the method further including setting a depth of the second depressed portion is to be smaller than a thickness of the wafer.

26. A vapor phase deposition method according to claim 25, further including
setting the depth of the second depressed portion so that a sum of a depth of the first depressed portion and the depth of the second depressed portion is smaller than the thickness of the wafer.

27. A support table adapted to be accommodated in a chamber of a vapor phase deposition apparatus to support a substrate on which a film is to be formed with gas that is supplied to the chamber, the support table comprising:
a holder;
a first depressed portion formed on the holder; and
a second depressed portion formed on a bottom part of the first depressed portion, a bottom face of the second depressed portion being for supporting the substrate.
